(19) United States
(12) Patent Application Publication
(10) Pub. No.: US 2013/0077230 A1
(43) Pub. Date: Mar. 28, 2013

(54) HOUSING AND DISC DRIVE INCLUDING THE HOUSING

(71) Applicants: Seong-uk Jeon, Seoul (KR); Sang-yun Lee, Suwon-si (KR)

(72) Inventors: Seong-uk Jeon, Seoul (KR); Sang-yun Lee, Suwon-si (KR)

(21) Appl. No.: 13/564,075

(22) Filed: Aug. 1, 2012

(30) Foreign Application Priority Data
Sep. 26, 2011 (KR) 10-2011-0096985

(51) Int. Cl. H05K 5/03; G06F 1/16

(52) U.S. Cl. 361/679.33; 312/223.2

(57) ABSTRACT

Provided is a housing for an optical disk drive that locks an upper cover and a lower cover without the use of a screw or bolt. The lower cover includes complementary projections that are formed on side plates and the upper cover includes hook-type projection openings that correspond to the complementary projections.

### CROSS-REFERENCE TO RELATED APPLICATION(S)

This application claims the benefit under 35 USC §119(a) of Korean Patent Application No. 10-2011-0096985, filed on Sep. 26, 2011, in the Korean Intellectual Property Office, the entire disclosure of which is incorporated herein by reference for all purposes.

### BACKGROUND

1. Field

The following description relates to a housing and a disc drive adopting the housing, and in particular, to a housing that has an improved coupling structure.

2. Description of Related Art

Typically, the housing of an optical disc drive includes an upper cover and a lower cover which cover upper and lower portions of a main frame of the optical disc drive. The upper cover includes a top plate that is located above the main frame and side plates corresponding to side surfaces of the main frame.

In general, the upper cover and the lower cover of the housing are coupled to the main frame using a screw. To decrease production costs, the number of parts and the number of processes for producing the housing should be reduced.

### SUMMARY

In an aspect, there is provided a housing for an optical disc drive, the housing including an upper cover comprising a top plate and side plates that face each other and which are located on opposite sides of the top plate, a lower cover corresponding to the top plate, hook-type projection openings that are formed at facing edges of the lower cover corresponding to the side plates and which each have a projection extending parallel to the side plates, and complementary projections that are formed on the side plates of the upper cover and which correspond to the hook-type projection openings of the lower cover.

The complementary projections may extend toward the inside of the upper cover.

Flanges corresponding to the side plates of the upper cover may be formed at facing edges of the lower cover, holding members may be formed at edges of the side plates of the upper cover to correspond to edges of the side plate of the lower cover, and are disposed parallel to each other at predetermined intervals with respect to the side plates, and the flanges of the lower cover may be configured to be inserted into gaps between the side plates and the holding members of the upper cover.

The complementary projections may be integrally formed with the side plates, and extend in a direction perpendicular to the flanges.

When a complementary projection is restricted by a projection of a corresponding hook-type projection opening, a surface of the complementary projection may contact an inner surface of the lower cover.

In an aspect, there is provided a housing for an optical disc drive, the housing including an upper cover comprising a top plate located above a main frame included in the optical disc drive and side plates that correspond to sides of the main frame, a lower cover located under the main frame, hook-type projection openings that are formed at facing edges of the lower cover corresponding to the side plates and which each have a projection extending parallel to the side plates, and complementary projections that are formed on the side plates of the upper cover and which correspond to the hook-type projection openings of the lower cover.

The main frame may comprise an elastic location determination unit protruding toward the lower cover, and the lower cover may have a location determination hole that couples to the elastic location determination unit.

The complementary projections may extend toward the inside of the upper cover.

Flanges corresponding to the side plates of the upper cover may be formed at facing edges of the lower cover, holding members may be formed at edges of the side plates of the upper cover to correspond to edges of the side plate of the lower cover, and are disposed parallel to each other at predetermined intervals with respect to the side plates of the upper cover, and the flanges of the lower cover may be configured to be inserted into gaps between the side plates and the holding members of the upper cover.

The complementary projections may be integrally formed with the side plates, and extend in a direction perpendicular to the flanges.

When a complementary projection is restricted by a projection of a corresponding hook-type projection opening, a surface of the complementary projection may contact an inner surface of the lower cover.

In an aspect, there is provided an optical disc drive including a main frame comprising a device for driving an optical disc, an optical pickup that accesses an information recording surface of the optical disc, and an optical pickup transport device for transporting the optical pickup, an upper cover comprising a top plate located above the main frame and side plates corresponding to sides of the main frame, a lower cover disposed under the main frame, hook-type projection openings that are formed at facing edges of the lower cover corresponding to the side plates and which each have a projection extending parallel to the side plates, and complementary projections that are formed on the side plates of the upper cover and which correspond to the hook-type projection openings of the lower cover.

The main frame may comprise an elastic location determination unit protruding toward the lower cover, and the lower cover may comprise a location determination hole that couples to the elastic location determination unit.

The complementary projections may extend toward the inside of the upper cover.

Flanges corresponding to the side plates of the upper cover may be formed at facing edges of the lower cover, holding members may be formed at edges of the side plates of the upper cover to correspond edges of the side plate of the lower cover, and are disposed parallel to each other at predetermined intervals with respect to the side plates, and the flanges of the lower cover may be configured to be inserted into gaps between the side plates and the holding members of the upper cover.

The complementary projections may be integrally formed with the side plates, and extend in a direction perpendicular to the flanges.

When a complementary projection is restricted by a projection of a corresponding hook-type projection opening, a surface of the complementary projection may contact an inner surface of the lower cover.

In an aspect, there is provided a housing for an optical disc drive, the housing including an upper cover comprising opposing side walls that each have one or more projections extending outward in an X direction, and a lower cover comprising opposing flanges that each have one or more complementary projection openings that are configured to slidably receive the one or more projections of the upper cover in a Y direction, wherein the upper cover and the lower cover are prevented from moving in a Z direction, in response to the upper cover and the lower cover being slid with respect to each other in the Y direction such that the projections respectively lock with the complementary projection openings.

Other features and aspects may be apparent from the following detailed description, the drawings, and the claims.

### BRIEF DESCRIPTION OF THE DRAWINGS

FIG. 1 is a diagram illustrating an example of an exploded view of an optical disc drive.

FIG. 2 is a diagram illustrating an example of a housing for an optical disc drive.

FIG. 3 is a diagram illustrating an example of an upside-down view of the housing of FIG. 2.

FIG. 4 is a diagram illustrating an example of a coupling structure of a skirt of an upper cover of a housing and a flange of a lower cover of the housing.

FIG. 5 is a diagram illustrating an example of a front view of the housing of FIG. 4 in which the skirt of the upper cover is not yet coupled to the flange of the lower cover.

FIG. 6 is a diagram illustrating an example of a front view of the housing of FIG. 4 in which the skirt of the upper cover is coupled to the flange of the lower cover.

FIG. 7 is a diagram illustrating an example of a cross-sectional view taken along line A-A of the housing shown in FIG. 6.

FIG. 8 is a diagram illustrating an example of a bottom of the housing in which the housing and a main frame are coupled together.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

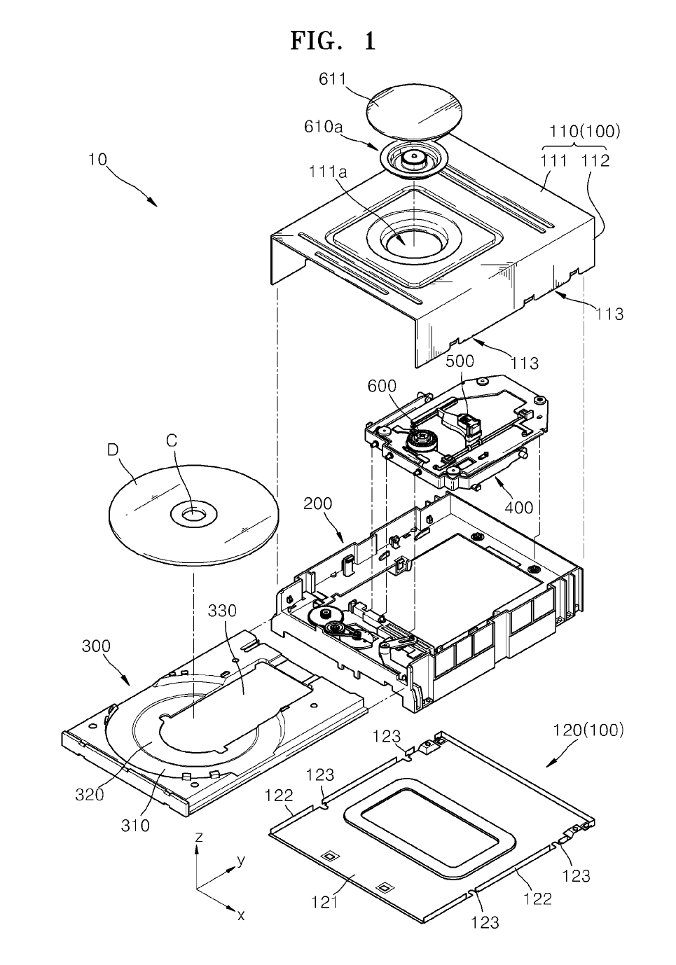

FIG. 1 illustrates an example of an exploded view of an optical disc drive 10 that includes a housing 100. For example, the optical disc drive 10 may be included in a terminal such as a computer, a DVD player, a Blu-ray player, a compact disc player, a television, a video game console, and the like.

Referring to FIG. 1, the housing 100 includes an upper cover 110 and a lower cover 120 which are located above and below a main frame 200, respectively. The optical disc drive 10 includes the main frame 200 that is housed by the housing 100, and a tray 300 on which an optical disc D may be mounted and which may be inserted into and released from the main frame 200. A clamper 610a for fixing the optical disc D on a turntable 600 is mounted on the upper cover 110. The clamper 610a is located at an opening 111a of the upper cover 110. In this example, the opening 111 a is covered by a cap 611 to protect the clamper 610a.

The tray 300 may have a first installation portion 310 on which an optical disc D having a diameter of 120 mm may be placed and a second installation portion 320 on which an optical disc (not shown) having a diameter of 80 mm may be placed. The location of the center of the tray 300 corresponds to the turntable 600 on which the optical disc D is mounted and an open window 330 where an optical pickup unit 500 is located.

Like in a typical optical disc drive, the optical disc drive 10 includes a main base 400 that moves up and down with respect to the main frame 200. The main base 400 may include the turntable 600 that rotates the optical disc D, and the optical pickup unit 500 that accesses an information recording surface of the optical disc D.

The main base 400 is rotatably supported with respect to the main frame 200. When the tray 300 moves in a a positive (+) y direction such that the tray 300 moves into the main frame 200, the main base 400 moves in a positive (+) z direction in which the turntable 600 is lifted upward. The movement causes the optical disc D to be lifted upward between the turntable 600 and the clamper 610a. Accordingly, the optical disc D may synchronize with the rotation of the turntable 600, and thus, can be rotated at a high speed.

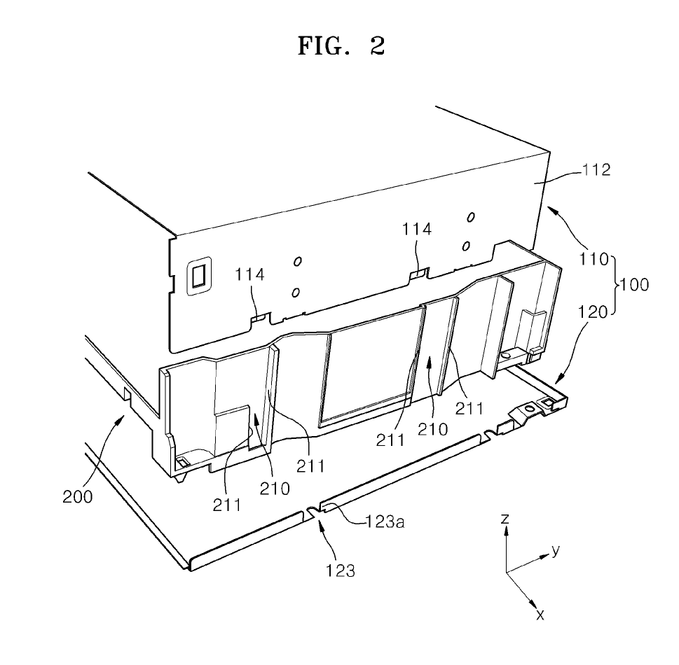

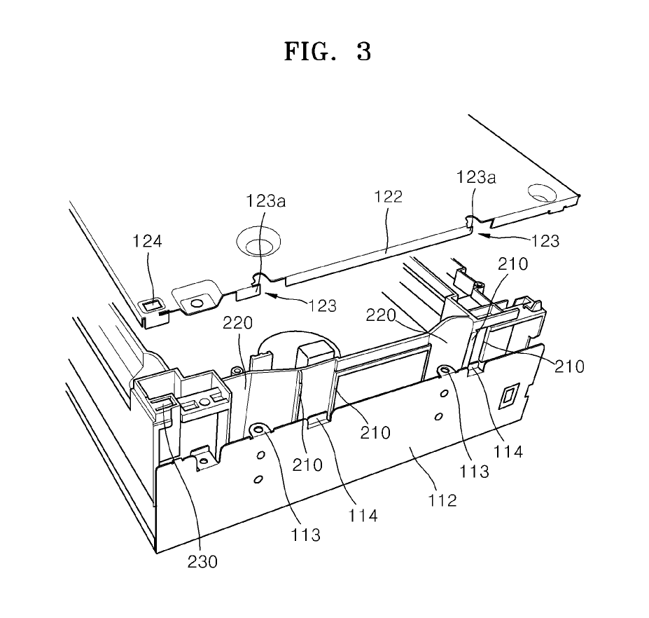

FIG. 2 illustrates an example of the housing 100 and the main frame 200 housed by the housing 100. FIG. 3 illustrates an example of an upside-down view of the housing 100.

Referring to FIGS. 2 and 3, the housing 100 includes the upper cover 110 and the lower cover 120. The lower cover 120 includes facing flanges 122 and a plurality of hook-type projection openings 123 (also referred to as hook-type projection openings 123) facing side plates 112 of the upper cover 110. On an opposite side thereof, the upper cover 110 includes a plurality of complementary projections 113 that correspond to the hook-type projection openings 123 and that engage with the hook-type projection openings 123 due to their complementary structures.

For example, the lower cover 120 may include hook-type projection openings 123 on flanges 122 on opposing sides of the lower cover 120. Likewise, the upper cover 110 may include complementary projections 113 on opposing side plates 112 of the upper cover 110. The lower cover may include a body and the flanges 122 may be located on opposing sides of the body. The upper cover 110 may include a top plate that corresponds in size to the body of the lower cover. The side plates 112 may be located on opposing sides of the top plate. When locked together, the top plate of the upper cover 110 may face the body of the lower cover 120.

The hook-type projection openings 123 of the lower cover 120 may each have a projection 123a that extends in a direction parallel (a direction parallel to the y direction) to the side plates 112 of the upper cover 110 of the main frame 200. Each of the complementary projections 113 has a surface extending in an x-axis direction. The lower plate 120 and the upper plate 110 may be slid together so that the projection 123a of the hook-type projection step 123 moves in the y-axis direction under the complementary projection step 113 to couple with the complementary projection step 113, thereby restricting z-directional movements of the upper and lower covers 110 and 120. For example, a manufacturer or a user may slide the upper and lower covers 110 and 120 together. In this example, the z direction is a direction in which the upper cover 110 and the lower cover 120 are separated from each other.

The main frame located between the upper and lower covers 110 and 120 includes a guide channel 210 that guides an L-type holding member 114 located on the side plate 112 of the upper cover 110. For example, the guide channel 210 may include walls 211 that have a predetermined height in a lengthwise direction on both sides of the main frame 200. Like the guide channel 210, the main frame 200 may also include a concave channel 220 that protrudes toward the inside of the side plates 112 of the upper cover 110 and that allows passage of the complementary projection step 113. The concave channel 220 is formed on the side surface of the main frame 200.

The holding member 114 of the upper cover 110 determines a location of the upper cover 110 with respect to the main frame 200 in the y direction, and may allow the upper cover 110 to move with respect to the main frame 200 in the z direction and prevent the upper cover 110 from moving in the y direction with respect to the main frame 200. The holding member 114 may be formed by cutting and bending a portion of the side plates 112. Accordingly, when the upper cover 110 is coupled with the lower cover 120, the side plates 112 and the holding member 114 may firmly contact sides of the flange 122 of the lower cover 120, so that the side plates 112 and the flange 122 are stably coupled to each other.

An elastic location determination unit 230 is formed on a side of the main frame 200, and a location determination hole 124, which corresponds to the position of the elastic location determination unit 230, is formed on a complementary side of the lower cover 120. The location determination hole 124 and the location determination unit 230 face each other when the upper cover 110 and the lower cover 120 are combined with respect to the main frame 200. Accordingly, when the upper and lower covers 110 and 120 are coupled to each other by a hook structure as described herein, the coupling of the location determination hole 124 and the location determination unit 230 may be strongly maintained and may prevent the upper and lower covers 110 and 120 from being separated.

For example, when the elastic location determination unit is set to face the location determination hole 124, the elastic location determination unit 230 may elastically protrude in the z direction, thus locking the lower cover 120 and the main frame 200.

According to such a structure, the upper and lower covers 110 and 120 of the housing 100 are coupled to each other without additional coupling parts such as a screw and/or a bolt, and because of the location determination structure of the main frame 200 and the housing 100, the coupling is strongly fixed.

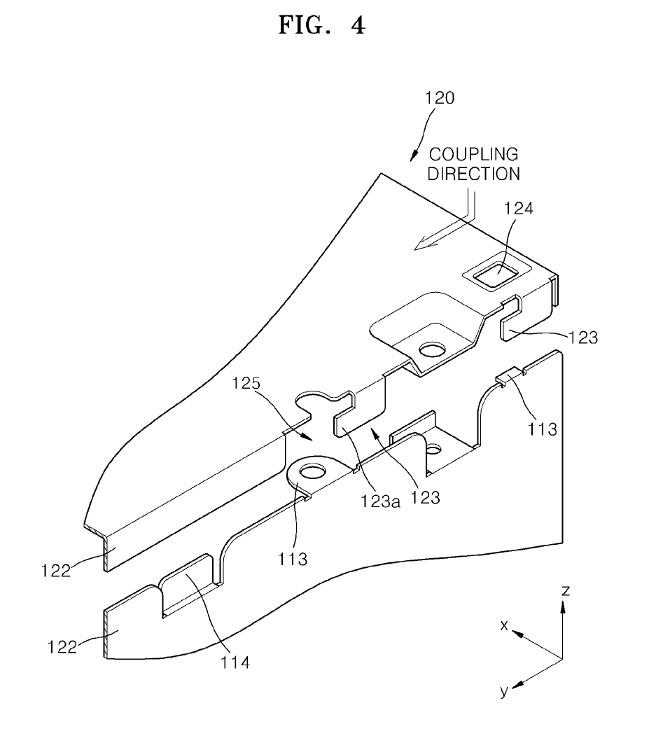

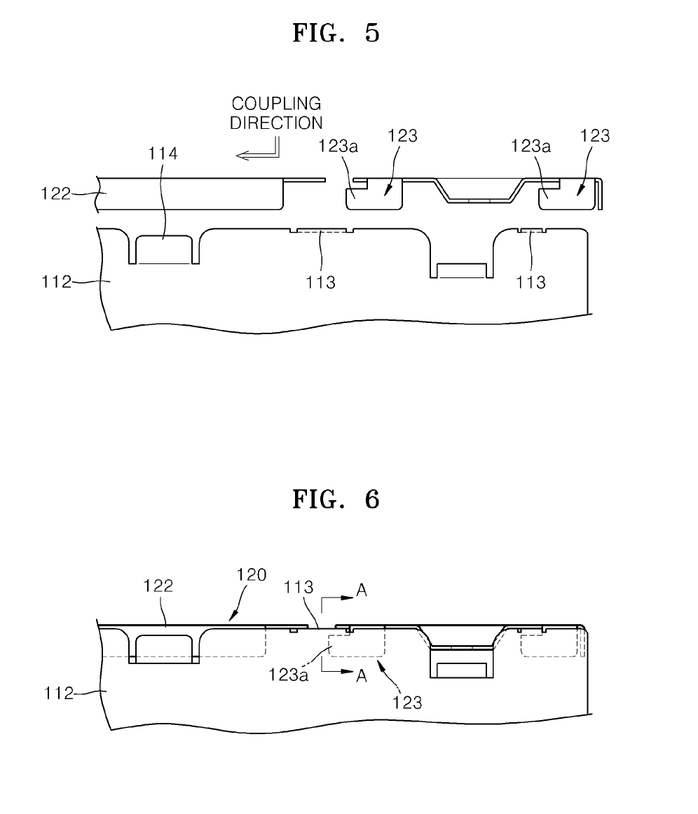

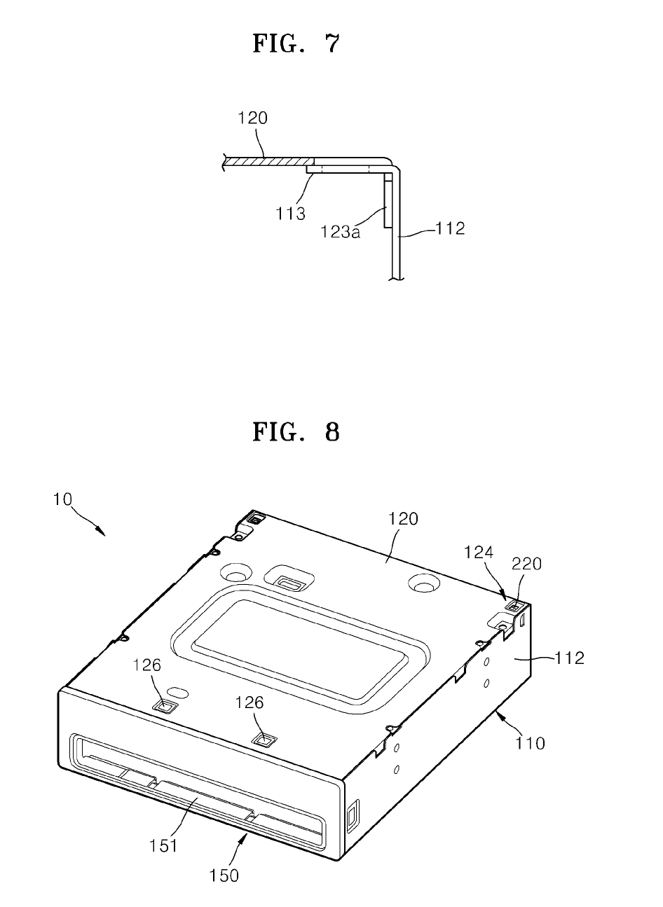

FIG. 4 illustrates an example of a hook structure of the upper cover 110 and the lower cover 120. FIG. 5 illustrates an example of a front view of the side plate 112 before the side plate 112 is coupled to the flanges 122. FIG. 6 illustrates an example of a front view of the side plate 112 in which the side plate 112 is coupled to the flanges 122. FIG. 7 illustrates an example of a cross-sectional view taken along line A-A of the housing shown in FIG. 6.

Referring to FIGS. 4 and 5, an upper portion of the illustrated structure is the lower cover 120 and a lower portion of the illustrated structure is the side plate 112 of the upper cover 110.

The flange 122 is formed along an edge of the lower cover 120, and the hook-type projection step 123 is formed along the flange 122. At one end of the hook-type projection step 123, the projection 123a extends in a negative (−) y direction that is parallel to the planar surface of the side plate 122.

The complementary projection step 113 that corresponds to the hook-type projection step 123 is formed at the edge of the side plate 112 of the upper cover 110. The complementary projection step 113 extends from the side plate 112 of the upper cover 110 and is disposed in the x direction. The complementary projection step 113 of the upper cover 110 enters the lower cover 120 between an opening 125 and a fore-end of the projection 123a of the hook-type projection step 123 of the lower cover 120 and the side plate 122 facing the fore-end. Through the opening 125, the complementary projection step 113 enters under the projection 123a of the hook-type projection step 123. As illustrated in FIG. 7, a surface of the complementary projection step 113 contacts an inner side of the lower cover 120. Accordingly, when the lower cover 120 and the upper cover move along the coupling direction, the complementary projection step 113 may slide from the opening 125 to the projection 123a, and thus, the lower cover 120 and upper cover 110 may lock in place.

It should be appreciated that the locations of the hook-type projection step 123 and the corresponding complementary projection step 113 are not limited to the examples shown herein. For example, the hook-type projection step 123 may be formed on the side plate 112 of the upper cover 110, and the complementary projection step 113 may be formed on the lower cover 120. According to another example, the projection 123a of the hook-type projection step 123 may extend in a positive y direction, and the direction of the complementary projection step 113 may be changed correspondingly. For example, with reference to FIG. 4, the coupling direction of the lower cover 120 with respect to the upper cover 110 is from a rear side to a front side of the upper cover 110. However, as described above, by changing orientations of the projection 123a of the hook-type projection step 123 and the complementary projection step 113, the coupling direction may be changed.

FIG. 8 illustrates an example of the optical disc drive 10 in which the main frame 200 is coupled to the housing 100. An upper portion of the illustrated structure is a bottom of the optical disc drive 10, that is, the lower cover 120.

A bezel 150 has an opening 151 through which the tray enters and is formed at the front of the housing 100. A hole 126 formed at the front of the lower cover 120 is formed to fix the bezel 150. The hole 126 may be the same or may be similar in size as the location determination hole 124.

According various aspects, a housing is assembled without coupling parts such as a screw or a bolt. In various aspects, a housing is completely coupled to a main frame without coupling parts. Accordingly, a reduction in manufacture cost due to the non-use of additional coupling parts and a reduction in the number of processes for assembling coupling parts can be achieved, and thus, process costs may be reduced.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A housing for an optical disc drive, the housing comprising:
an upper cover comprising a top plate and side plates that face each other and which are located on opposite sides of the top plate;
a lower cover corresponding to the top plate;
hook-type projection openings that are formed at facing edges of the lower cover corresponding to the side plates and which each have a projection extending parallel to the side plates; and
complementary projections that are formed on the side plates of the upper cover and which correspond to the hook-type projection openings of the lower cover.

2. The housing of claim 1, wherein the complementary projections extend toward the inside of the upper cover.

3. The housing of claim 1, wherein flanges corresponding to the side plates of the upper cover are formed at facing edges of the lower cover;
holding members are formed at edges of the side plates of the upper cover to correspond to edges of the side plate of the lower cover, and are disposed parallel to each other at predetermined intervals with respect to the side plates; and
the flanges of the lower cover are configured to be inserted into gaps between the side plates and the holding members of the upper cover.

4. The housing of claim 3, wherein the complementary projections are integrally formed with the side plates, and extend in a direction perpendicular to the flanges.

5. The housing of claim 3, wherein, when a complementary projection is restricted by a projection of a corresponding hook-type projection opening, a surface of the complementary projection contacts an inner surface of the lower cover.

6. A housing for an optical disc drive, the housing comprising:
an upper cover comprising a top plate located above a main frame included in the optical disc drive and side plates that correspond to sides of the main frame;
a lower cover located under the main frame;
hook-type projection openings that are formed at facing edges of the lower cover corresponding to the side plates and which each have a projection extending parallel to the side plates; and
complementary projections that are formed on the side plates of the upper cover and which correspond to the hook-type projection openings of the lower cover.

7. The housing of claim 6, wherein the main frame comprises an elastic location determination unit protruding toward the lower cover, and
the lower cover has a location determination hole that couples to the elastic location determination unit.

8. The housing of claim 6, wherein the complementary projections extend toward the inside of the upper cover.

9. The housing of claim 6, wherein flanges corresponding to the side plates of the upper cover are formed at facing edges of the lower cover,
holding members are formed at edges of the side plates of the upper cover to correspond to edges of the side plate of the lower cover, and are disposed parallel to each other at predetermined intervals with respect to the side plates of the upper cover; and
the flanges of the lower cover are configured to be inserted into gaps between the side plates and the holding members of the upper cover.

10. The housing of claim 9, wherein the complementary projections are integrally formed with the side plates, and extend in a direction perpendicular to the flanges.

11. The housing of claim 10, wherein, when a complementary projection is restricted by a projection of a corresponding hook-type projection opening, a surface of the complementary projection contacts an inner surface of the lower cover.

12. An optical disc drive comprising:
a main frame comprising a device for driving an optical disc, an optical pickup that accesses an information recording surface of the optical disc, and an optical pickup transport device for transporting the optical pickup;
an upper cover comprising a top plate located above the main frame and side plates corresponding to sides of the main frame;
a lower cover disposed under the main frame;
hook-type projection openings that are formed at facing edges of the lower cover corresponding to the side plates and which each have a projection extending parallel to the side plates; and
complementary projections that are formed on the side plates of the upper cover and which correspond to the hook-type projection openings of the lower cover.

13. The optical disc drive of claim 14, wherein the main frame comprises an elastic location determination unit protruding toward the lower cover, and
the lower cover comprises a location determination hole that couples to the elastic location determination unit.

14. The optical disc drive of claim 14, wherein the complementary projections extend toward the inside of the upper cover.

15. The optical disc drive of claim 14, wherein flanges corresponding to the side plates of the upper cover are formed at facing edges of the lower cover,
holding members are formed at edges of the side plates of the upper cover to correspond edges of the side plate of the lower cover, and are disposed parallel to each other at predetermined intervals with respect to the side plates; and
the flanges of the lower cover are configured to be inserted into gaps between the side plates and the holding members of the upper cover.

16. The optical disc drive of claim 17, wherein the complementary projections are integrally formed with the side plates, and extend in a direction perpendicular to the flanges.

17. The optical disc drive of claim 17, wherein, when a complementary projection is restricted by a projection of a corresponding hook-type projection opening, a surface of the complementary projection contacts an inner surface of the lower cover.

18. A housing for an optical disc drive, the housing comprising:
an upper cover comprising opposing side walls that each have one or more projections extending outward in an X direction; and
a lower cover comprising opposing flanges that each have one or more complementary projection openings that are configured to slidably receive the one or more projections of the upper cover in a Y direction,
wherein the upper cover and the lower cover are prevented from moving in a Z direction, in response to the upper cover and the lower cover being slid with respect to each other in the Y direction such that the projections respectively lock with the complementary projection openings.
